(19) United States
(12) Patent Application Publication
(10) Pub. No.: US 2007/0093067 A1
(43) Pub. Date: Apr. 26, 2007

(54) Wafer edge cleaning process

(75) Inventors: Ching-Yu Chang, Yuansun Village (TW); Burn Jeng Lin, Hsin-Chu (TW)

Correspondence Address: HAYNES AND BOONE, LLP, 901 MAIN STREET, SUITE 3100, DALLAS, TX, 75202, US

(73) Assignee: Taiwan Semiconductor Manufacturing Company, Ltd., Hsin-Chu (TW)

(21) Appl. No.: 11/256,711

(22) Filed: Oct. 24, 2005

(51) Int. Cl. H01L 21/302; H01L 21/461

(52) U.S. Cl. 438/704; 438/745

(57) ABSTRACT

A method of processing a semiconductor wafer can be used prior to an immersion lithography process. The method includes providing a layer of organic photoresist onto a surface of the semiconductor wafer and removing a portion of the photoresist from an outer edge of the wafer using an edge-bead removal process. The outer edge of the wafer is then cleaned using one or more processes, including a mechanical scrubber/cleaner, mega-sonic power, de-ionized water and/or chemical solution.

This disclosure relates to U.S Provisional Ser. No. 60/695,826 filed Jun. 30, 2005, which is hereby incorporated by reference.

### BACKGROUND

The present disclosure relates to cleaning the edge of a substrate such as a semiconductor wafer. This can be used with various processes, an example being immersion lithography.

Lithography is a mechanism by which a pattern on a mask is projected onto a substrate such as a semiconductor wafer. In areas such as semiconductor photolithography, it has become necessary to create images on the semiconductor wafer which incorporate minimum feature sizes under a resolution limit or critical dimension (CD). Currently, CDs are reaching 65 nanometers and less.

Immersion lithography is a new advance in photolithography, in which the exposure procedure is performed with a liquid filling the space between the surface of the wafer and the lens. Using immersion photolithography, higher numerical apertures can be built than when using lenses in air, resulting in improved resolution. Further, immersion provides enhanced depth-of-focus (DOF) for printing ever smaller features.

The immersion exposure step may use de-ionized water or another suitable immersion exposure fluid in the space between the wafer and the lens. Though the exposure time is short, the combination of the fluid and the photoresist (resist) can cause heretofore unforeseen problems. For example, particles that exist on an edge of the wafer being exposed can come into contact with the immersion exposure fluid and/or the lens, thereby causing defects on the wafer.

It is desired to reduce particles, such as those found on a wafer's edge, to improve overall processing quality. This is important in various processes, such as in an immersion lithography process.

### BRIEF DESCRIPTION OF THE DRAWINGS

The present disclosure is best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a flow chart of a process flow using a wafer edge cleaning process according to one embodiment of the present invention. The process flow can be, for example, an immersion lithography process.

FIG. 2 is a side-view diagram of an immersion lithography system.

FIG. 3 is a view of the semiconductor wafer that has been processed from the immersion lithography system of FIG. 2 and that is suffering from one or more defects.

FIGS. 4-6 are views of different wafer edge cleaning processes according to one or more embodiments of the present invention.

### DETAILED DESCRIPTION

The present disclosure relates generally to the fabrication of semiconductor devices, and more particularly, to a method and system for the removing particles from a semiconductor substrate. It is understood, however, that specific embodiments are provided as examples to teach the broader inventive concept, and one of ordinary skill in the art can easily apply the teachings of the present disclosure to other methods and systems. Also, it is understood that the methods and systems discussed in the present disclosure include some conventional structures and/or steps. Since these structures and steps are well known in the art, they will only be discussed in a general level of detail. Furthermore, reference numbers are repeated throughout the drawings for the sake of convenience and clarity, and such repetition does not indicate any required combination of features or steps throughout the drawings. Further still, intermediate layers and/or processing steps can be used throughout the following disclosure, as is well known in the art, without deviating from the general spirit of the invention.

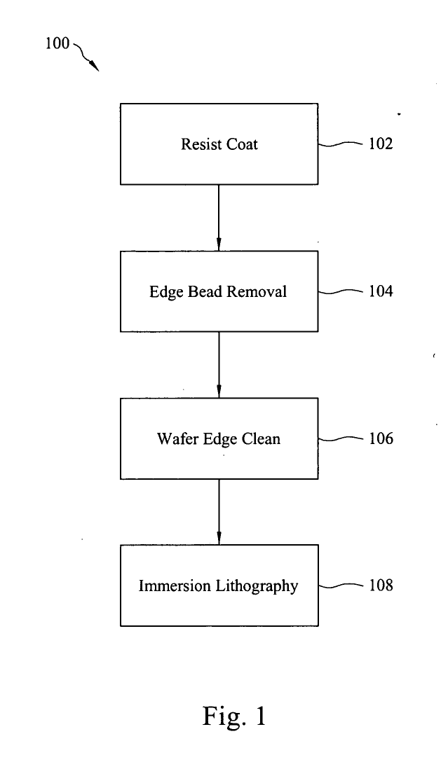

Referring to FIG. 1, a simplified flowchart of an embodiment of a wafer fabrication process which results in a reduced number of particles/defects is designated with the reference numeral 100. Execution begins at step 102, where an organic polymer photoresist (resist) layer is formed over the surface (e.g., a thin film stack) of a wafer substrate. The resist may be a negative or positive resist and may be of a material now known or later developed for this purpose. For example, the resist may be a one- two- or multi-component resist system. The application of the resist may be done with spin-coating or another suitable procedure. Prior to the application of the resist, the wafer may be first processed to prepare it for the photolithography process. For example, the wafer may be cleaned, dried and/or coated with an adhesion-promoting material prior to the application of the resist. Also, a bottom anti-reflective coating (BARC) layer may be placed on the wafer before the resist is applied, and/or a top anti-reflective coating (TARC) layer may be placed on the wafer after the resist is applied.

At step 104, a solvent rinse is applied to remove the resist at the wafer's edge (referred to as “edge-bead”). This process helps to prevent the resist from contaminating during the exposure process. A conventional edge-bead removal (EBR) process includes the following parameters shown in Table 1 below. It is a two step process, where the first step spins the wafer at 1000 revolutions per minute for 5 seconds. During this step, two nozzles for dispensing solvent are positioned 1.5 millimeters from the wafer edge, one for the front surface of the wafer, the other for the back surface. It is understood that the terms “front” refer to the side of the wafer with the resist, and “back” refers to the opposite side.

TABLE 1

| Step | R.P.M. | Time (secs) | Nozzle Position (mm) | Fluid Dispense |
|---|---|---|---|---|
| 1 | 1000 | 5 | 1.5 | front and back |
| 2 | 1000 | 5 | — | none (spin dry) |

In another embodiment, an improved EBR process, such as is shown in presently incorporated U.S. Ser. No. 60/695,826, can be used.

At step 106, a wafer edge cleaning process is performed. The wafer edge cleaning process is performed after the EBR process to remove any particles left by the EBR process. The wafer edge cleaning process can include mechanical and/or chemical components, as discussed in greater detail below.

At step 108, additional processing can be performed. One example of a process that can benefit from the present invention is an immersion lithography process. In furtherance of this example, the wafer and resist (and any other layers) are immersed in an immersion exposure liquid such as de-ionized water, and exposed to a radiation source. The radiation source may be an ultraviolet light source, for example a krypton fluoride (KrF, 248 nm), argon fluoride (ArF, 193 nm), or F₂ (157 nm) excimer laser. The wafer is exposed to the radiation for a predetermined amount of time, which is dependent on the type of resist used, the intensity of the ultraviolet light source, and/or other factors. The exposure time may last from about 0.2 seconds to about 30 seconds, for example. After exposure, a post-exposure bake (PEB) is performed for polymer cleavage and a developing process is used to complete the patterning of the resist layer.

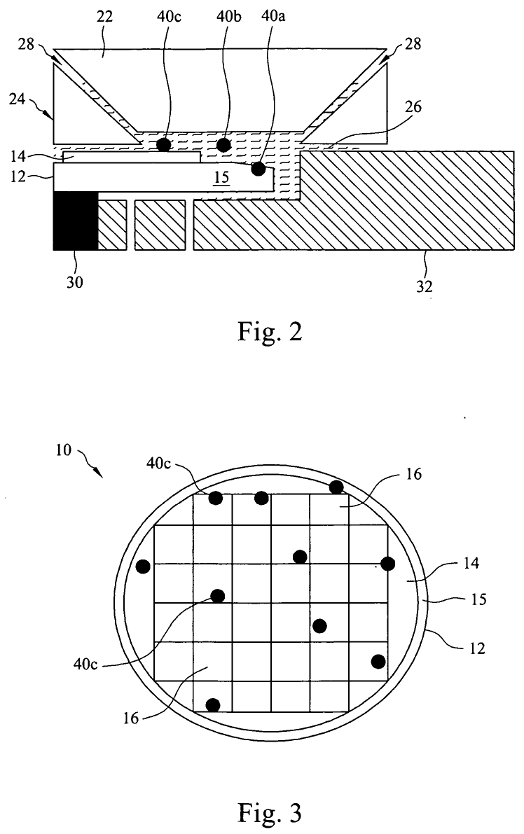

Referring to FIG. 2, a semiconductor wafer 10 is one example of an item that can be processed by the above-referenced process 100. The wafer 10 includes a substrate 12 and a patterning layer 14. The substrate 12 can include one or more layers, including poly, metal, and/or dielectric, that are desired to be patterned. The patterning layer 14 can be a photoresist (resist) layer that is responsive to an exposure process for creating patterns. The patterning layer 14 is removed from the substrate 12 at the wafer edge 15. In the present embodiment, a plurality of die 16 are being formed on the wafer 10. Although not required, the wafer 10 may include a bottom anti-reflective coating (BARC) layer and/or a top anti-reflective coating (TARC) layer, as well as various other layers.

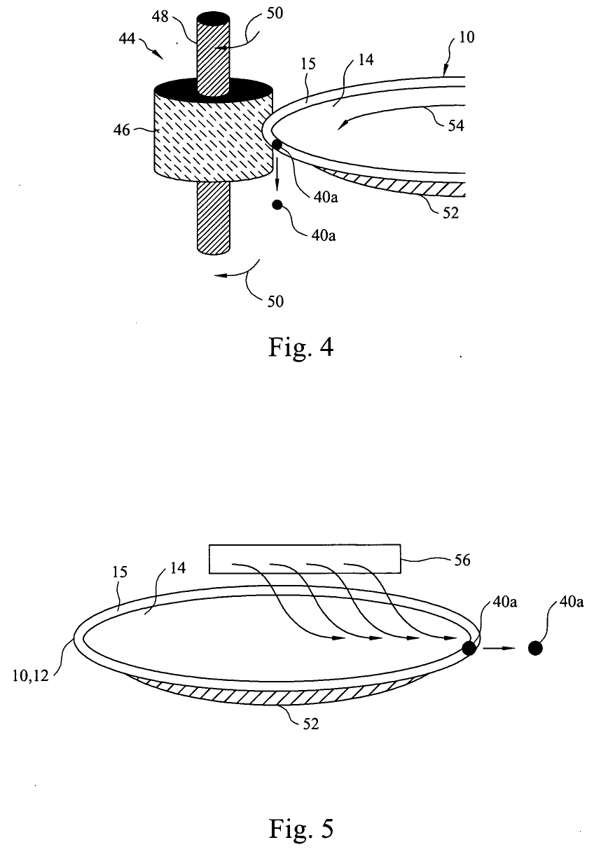

Referring to FIG. 3, in a conventional process, the wafer 10 is provided to an immersion lithography system 20 directly after the EBR process 104. The immersion lithography system 20 includes a lens system 22, an immersion head 24 for containing a fluid 26 such as de-ionized water, various apertures 28 through which fluid can be added or removed, and a chuck 30 for securing and moving the wafer 10 relative to the lens system 22. The chuck 30 further includes a structure 32 for containing the fluid 26. In FIG. 3, the lens system 22 and immersion head 24 are positioned near the right edge 15 of the wafer 10. It is understood that the lens 22 and the wafer 10 experience relative movement so that the lens can expose the resist layer 14 over the entire wafer.

Although not intended to be limiting, a fault mechanism for causing defects during a conventional immersion lithography process occurs when particles are left over from the EBR process 104. For the sake of example, particles 40a exist on the edge of the wafer 10 immediately after the EBR process 104. The particles, now designated 40b, mix with the immersion processing fluid 26 during lithography. The particles, now designated 40c, deposit or otherwise alter the wafer 10 at various locations. Referring also to FIG. 2, the particle 40c can contaminate the die 16, potentially causing failures. The particles 40 may then cause defects on the wafer 10, as is well known in the art.

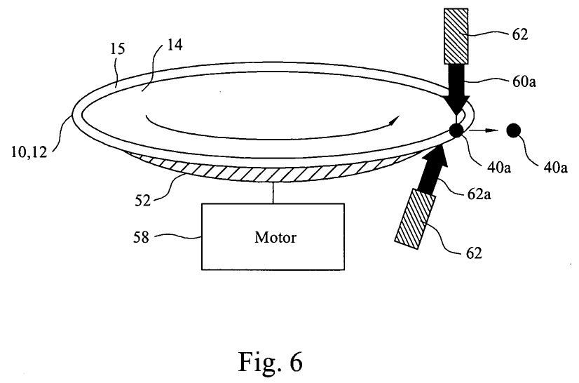

Referring again to the process 100 of FIG. 1, the amount of particles 40a that exist on the edge of the wafer 10 is reduced or eliminated by the wafer edge clean process 106 that occurs prior to the immersion lithography process 108. As a result, few, if any, particles 40c end up in the interior of the wafer 10 (e.g., at the die 16). Different embodiments of the wafer edge clean process 106 are described below with reference to FIGS. 4-6. Features of one embodiment can be used interchangeably with other embodiments to create even more embodiments, as discussed below.

Referring now to FIG. 4, in one embodiment, a mechanical scrubber/cleaner 44 can be used to clean the edge 15 of the wafer 10. In the present embodiment, the scrubber/cleaner 44 includes a head 46 that can be made of one or more different materials. Examples include mohair, polyvinyl acetate (PVA), sponge, and fibers. As a result, particles 40a are removed from the wafer 10. The particles 40a may be generally discarded, as illustrated in the picture, or may be absorbed in the scrubber/cleaner 44.

In one embodiment, the head 46 of the scrubber/cleaner 44 rotates about an axis 48 in a direction 50. The wafer 10 may be stationary or may also rotate. For example, the wafer 10 can reside on a chuck 52 and rotate a direction opposing to or consistent with the scrubber/cleaner direction 50. An arrow 54 shows the wafer 10 rotating in a direction consistent with the scrubber/cleaner direction 50. In a further embodiment, the wafer 10 and scrubber/cleaner 44 may rotate at the same angular velocity and in consistent directions so that the scrubber/cleaner has minimal opposing motion with the wafer edge 15.

In some embodiments, the scrubber/cleaner 44 can include one or more chemical solutions, such as de-ionized water, ozone (O3), hydrogen peroxide (H2O2), ammonium hydroxide and H202 (SC1), or a surfactant.

Referring now to FIG. 5, in another embodiment, an energy based or wave-based mechanism can be used to clean the edge 15 of the wafer 10. In the present embodiment, a mega-sonic power source 56 is applied to the wafer edge 15. As a result, particles 40a are removed from the wafer 10. In different embodiments, the wafer 10 may be rotated or stationary.

Referring now to FIG. 6, in another embodiment, a fluid and/or chemical process can be used to clean the edge 15 of the wafer 10. In the present embodiment, the wafer 10 is placed on the chuck 52 being driven by a motor 58, as well as one or more nozzles 60, 62. The two nozzles 60, 62 are positioned about on an inside portion of the wafer edge 15, for example about 1.5 millimeters from the outermost edge of the wafer. The nozzle 60 is illustrated as being perpendicular to the wafer 10's upper surface, while the nozzle 62 is illustrated as being at an angle. It is understood that various angles for both nozzles 60, 62 can be used in different embodiments.

The nozzles 60, 62 are used to eject a fluid 60a, 62a, respectively. The fluid can be one of many different fluids, including as de-ionized water, O3, SC1, surfactant, and/or air. Also, the nozzles 60, 62 can eject different fluids from each other and/or different fluids at different times.

As discussed above, various combinations of the above-described wafer edge clean processes can be used. For example, the cleaner/scrubber 44 can be used with the mega-sonic power 56 either together, or in sequential arrangement. For further example, the cleaner/scrubber 44 can be used, then the mega-sonic power 56 can be turned on during a cleaning processes for the cleaner/scrubber, and then the cleaner/scrubber can be used again. In another example, the mega-sonic power 56 can be used in conjunction with the chemical cleaning from the nozzles 60, 62.

Although only a few exemplary embodiments of this invention have been described in detail above, those skilled in the art will readily appreciate that many modifications are possible in the exemplary embodiments without materially departing from the novel teachings and advantages of this invention. It is understood that various different combinations of the above-listed treatment steps can be used in various sequences or in parallel, and there is no particular step that is critical or required. Also, features illustrated and discussed above with respect to some embodiments can be combined with features illustrated and discussed above with respect to other embodiments. Accordingly, all such modifications are intended to be included within the scope of this invention.

In one embodiment, a method of processing a semiconductor wafer is provided. The method includes providing a layer of material onto a surface of the semiconductor wafer and performing an edge-bead removal process to remove a portion of the resist from an outer edge of the semiconductor wafer. Afterwards, a wafer edge cleaning process is used to remove excess particles left over from the edge-bead removal process. This method can be used prior to various process operations, such as an immersion lithography process.

In some embodiments, the wafer edge cleaning process utilizes a mechanical edge cleaner. The mechanical edge cleaner may have a head comprising mohair and/or polyvinyl acetate (PVA).

In some embodiments, the wafer edge cleaning process utilizes a chemical edge cleaner. The chemical edge cleaner may utilize ozone (O3), hydrogen peroxide (H2O2), ammonium hydroxide and H202 (SC1), and/or surfactant.

In some embodiments, the wafer edge cleaning process utilizes de-ionized water.

In some embodiments, the wafer edge cleaning process utilizes a waves from an external power source, such as mega-sonic waves.

We claim:

1. A method of processing a semiconductor wafer, comprising:
providing a layer of material onto a surface of the semiconductor wafer;
performing an edge-bead removal process to remove a portion of the material from an outer edge of the semiconductor wafer; and
performing a wafer edge cleaning process after the edge-bead removal process.

2. The method of claim 1 further comprising:
performing a fluid-immersion process after the wafer edge cleaning process.

3. The method of claim 2, wherein the material is photoresist and the fluid-immersion process is an immersion lithography process.

4. The method of claim 1, wherein the step of performing the wafer edge cleaning process includes utilizing a mechanical edge cleaner.

5. The method of claim 4, wherein the mechanical edge cleaner comprises a head including at least one from a group consisting of mohair and polyvinyl acetate (PVA).

6. The method of claim 1, wherein the step of performing the wafer edge cleaning process includes utilizing a chemical edge cleaner.

7. The method of claim 6, wherein the chemical edge cleaner comprises at least one from a group consisting of ozone (O3), hydrogen peroxide (H2O2), ammonium hydroxide and H202 (SC1), and surfactant.

8. The method of claim 1, wherein the step of performing the wafer edge cleaning process includes utilizing de-ionized water.

9. The method of claim 1, wherein the step of performing the wafer edge cleaning process includes utilizing waves from an external power source.

10. The method of claim 9 wherein the waves are mega-sonic.

11. A method of particle removal, comprising:
providing a layer of organic photoresist onto a surface of a substrate;
removing a portion of the photoresist from an outer edge of the substrate using a solvent; and
cleaning the outer edge of the substrate using a solution.

12. The method of claim 11 wherein the solution is de-ionized water.

13. The method of claim 11 wherein the solution includes a chemical.

14. The method of claim 13 wherein the chemical is from a group consisting of ozone (O3), hydrogen peroxide (H2O2), ammonium hydroxide and H202 (SC1), and surfactant.

15. The method of claim 11 wherein the cleaning step also uses a mega-sonic power.

16. The method of claim 15 wherein the mega-sonic power and the solution are utilized to clean the outer edge of the substrate at the same time.

17. A method of removing particles from a semiconductor wafer prior to an immersion lithography process, the method comprising:
providing a layer of organic photoresist onto a surface of the semiconductor wafer;
removing a portion of the photoresist from an outer edge of the wafer using an edge-bead removal process; and
cleaning the outer edge of the substrate using a scrubber/cleaner.

18. The method of claim 17 further comprising:
cleaning the outer edge of the wafer using mega-sonic power.

19. The method of claim 18 wherein the mega-sonic power is provided intermittently with the operation of the scrubber/cleaner.

20. The method of claim 17 further comprising:
cleaning the outer edge of the substrate using de-ionized water or chemical solution.
